(19) United States
(12) Patent Application Publication
(10) Pub. No.: US 2024/0084438 A1
(43) Pub. Date: Mar. 14, 2024

(54) METHOD FOR FORMING AN LICOO2 FILM AND DEVICE FOR CARRYING OUT SAME

(71) Applicants: Iaroslav Anatolevich KOROLENKO, G. Moskva (RU); THE BATTERIES SP. ZO.O., Rzeszow (PL)

(72) Inventors: Iaroslav Anatolevich Korolenko, Moskow (RU); Airat Khamitovich KHISAMOV, Der.Borovlyany, Minskij r-n (BY); Sergei Mikhallovich NASTOCHKIN, Minsk (BY); Aleksandr Viktorovich ROSSOKHATYI, Verdun (CA)

(21) Appl. No.: 18/270,505

(22) PCT Filed: Dec. 30, 2021
(86) PCT No.: PCT/RU2021/050458

§ 371 Date: Jun. 30, 2023

(30) Foreign Application Priority Data
Dec. 30, 2020 (RU) 2020144125

(51) Int. Cl. C23C 14/08; C23C 14/00; C23C 14/35; H01J 37/34; H01M 4/04; H01M 4/1391; H01M 4/525

(52) U.S. Cl. CPC C23C 14/085; C23C 14/0063; C23C 14/35; H01J 37/3405; H01M 4/0426; H01M 4/1391; H01M 4/525; H01M 2004/028

(57) ABSTRACT

A method for forming a film of LiCoO2 involves applying to a substrate a layer of LiCoO2 from a metallic target of cobalt (Co) in vapours of lithium (Li) by reactive magnetron sputtering in a vacuum chamber. Lithium vapours are fed in a regulated manner to the magnetron through a gas distributor, connected to a working gas inlet and to a lithium feed inlet, by feeding a flow of a carrier gas through a heated lithium-containing reservoir which is heated to the melting point of lithium. The regulated feed of the lithium vapours is achieved by adjusting the flow of carrier gas through the heated reservoir. A device for forming a film of LiCoO2 comprises a vacuum chamber, and a magnetron with a metallic target of cobalt. On one side or about the perimeter of the magnetron is a gas distributor that is connected to a working gas inlet and, via a tap and/or a valve, to a heated lithium-containing reservoir that is connected to a carrier gas inlet. The gas distributor can be cellular or convoluted. The heated lithium-containing reservoir can be disposed inside or outside the vacuum chamber. The result is an increase in the deposition rate of a LiCoO2 film, an increase in the efficiency of the equipment and a reduction in the cost of mass-producing thin-film solid-state batteries.

### AREA OF TECHNOLOGY

The invention relates to the field of the technological equipment and technologies for mass production, in particular, vacuum equipment and vacuum technologies for functional thin film (cathode) formation (deposition) with required electrical, physical and chemical properties.

### LEVEL OF TECHNOLOGY

Magnetron technology is now widely used to form a LiCoO2 cathode layer in thin-film solid-state batteries (called batteries hereinafter). This method is applied on the basis of RF/MF/DC systems using composite targets with specific Li/Co concentration and with doping of other materials for achieving required physical and chemical properties of the LiCoO2 film.

The usage of such complex composite targets as well as the technology of thin film batteries production (magnetron sputtering from composite targets) limits both a choice of suppliers and productivity of deposition. The low productivity of magnetron methods and the high cost of equipment make the cost of producing solid state thin film batteries (batteries) very high. This prevents them from competing in the mass segment of consumer electronics. In addition, the usage of such composite targets strongly narrows the range of technological variability of the LiCoO2 layer. It narrows the range of technological variability of the LiCoO2 layer in terms of material concentration gradient formation by thickness, etc.

Also, the power limit for such targets should not exceed 5-10 W/cm2. At the same time, the deposition rate is typically not higher than 50-70 nm*m/min (for in-line equipment). These limits significantly reduce productivity and efficiency of the technological equipment and lead to increase a number of technological stations for LiCoO2 deposition (sputtering) or to use other solutions, resulting in high cost of materials and high cost of thin film battery production. And cost of thin film battery production increases exponentially with the area of substrate.

For example, a method of applying a lithium cobalt oxide film to a battery substrate in a sputtering chamber is known in the prior art. See. [1] U.S. Pat. No. 8,628,645, IPC C23C 14/00, published 14 Jan. 2014.

This method of application includes:
(a) placement of the substrate array on the substrate support;
(b) providing the first and second sputtering targets in the sputtering chamber. The first and second sputtering targets consist of lithium metal oxide (LiMeOx);
(c) maintaining a sputtering gas at a pressure in the sputtering chamber;
(d) energizing the sputtering gas by applying an alternating voltage from an AC power supply to the first and second electrodes at a frequency of between about 10 and about 100 kHz such that each of the first and second electrodes alternately serves as an anode or a cathode;
(e) rotating the first and second rotatable magnet assemblies at a rotational frequency of between about 0.005 and about 0.1 Hz to provide a variable magnetic field about the first and second sputtering targets.

The appliance for carrying out the method contains:
(i) support for the substrate;
(ii) the first and second sputtering targets;
(iii) the first electrode which contacts the rear surface of the first sputtering target. The second electrode which contacts the rear surface of the second sputtering target;
(iv) a first magnetron which contains a first rotating magnet assembly behind the first sputtering target. The second magnetron contains a second rotating magnet assembly behind the second sputtering target.

The disadvantage of the analogue is the low deposition rate of the lithium metal oxide (LiMeOx) layer.

The disadvantage of the analogue is also the high cost of production of a thin film solid-state battery due to the usage of a LiCoO2 targets.

### The Essence of the Invention

The aims of this invention for LiCoO2 cathode film deposition for mass production are to increase of LiCoO2 film deposition rate (and hence to increase the productivity of equipment) and to change the raw materials for LiCoO2 film deposition from complex composite LiCoO2 targets to a simple and cheap materials (metal cobalt (Co) targets and metal lithium (Li) pellets). These processes are the objectives of this invention.

The technical result of the claimed invention is a radical reduction in the cost of mass production of thin-film solid-state batteries (accumulators) in comparison with current magnetron sputtering technology.

According to the invention the technical task is solved. Technical result is achieved by using the method of LiCoO2 film formation (deposition), which includes LiCoO2 deposition from metal cobalt (Co) target in lithium (Li) vapor based on reactive magnetron sputtering in vacuum chamber. Control of lithium vapor flow into vacuum chamber is realized through the gas distributor, which is connected to input of working gas and to input of lithium vapor such as from the tank. Lithium vapor flow is realized by pumping of gas-carrier flow through heated tank with lithium, heated to lithium melting point. Control of lithium vapor flow is realized by changing the flow of gas-carrier through heated tank with lithium.

Technical result is achieved by using the technological device for LiCoO2 film deposition, which includes vacuum chamber, magnetron system with metal cobalt target, gas distributor, which is placed on perimeter or on the side of the magnetron system.

Gas distributor is connected to the input of the working gas and to the input of the heated tank with lithium through the valves; the heated tank with lithium is connected with the input of gas-carrier.

The technical result is also achieved by the fact that the gas distributor can be de-signed as a cavity or a labyrinth.

The technical result is also achieved by the fact that the heated lithium tank can be located inside or outside the vacuum chamber.

### BRIEF DESCRIPTION OF THE DRAWINGS

FIG. 1—Schematic diagram of the LiCoO2 layer forming device.

FIG. 2—Schematic diagram of a lithium vapor tank.

The following positions are marked on the figures:
1—vacuum chamber;
2—magnetron (system);
3—gas distributor;
4—heated tank;
5—spectrometer;
6—door for loading/unloading the lithium cassette;
7—lithium cassette;
8—heater;
9—nozzle for gas-carrier connection

### EXECUTION OF THE INVENTION

The method for LiCoO2 thin film formation (deposition) on the substrate is a technology of reactive magnetron sputtering from metal cobalt target in lithium vapor. Sub-strates may be silicon wafers, mica sheets, or other materials.

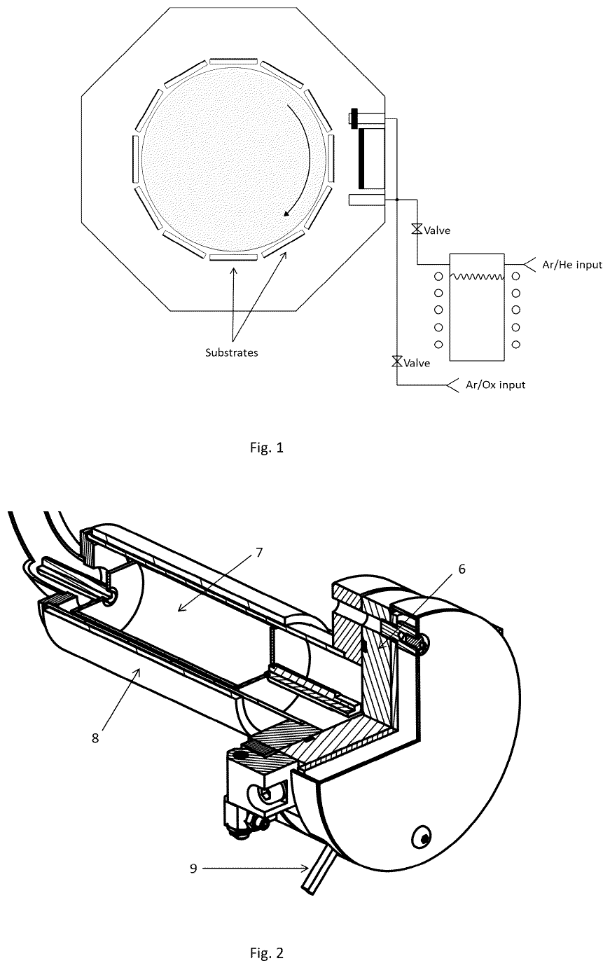

FIG. 1 shows the technological device for LiCoO2 thin film formation (deposition). It includes vacuum chamber (1) with magnetron system (2) and metal cobalt target.

The magnetron system (2) is a DC/AC magnetron with a magnetic system and an magnetic field (e.g. over 800 Gs). A gas distributor (3) is installed around the perimeter or on one side of the magnetron. This gas distributor is heated to 600-800 degrees Celsius. In the simplest case it may be a cavity distributor. In more complex versions it may be a labyrinth distributor. This gas distributor is connected via valves and/or taps to the working gas inlet and to a heated lithium tank (4) (lithium source).

This tank can be installed either inside or outside of the vacuum chamber. The lithium source (FIG. 2) is a heated tank (4) heated to 600 degrees Celsius. It is a tank or reservoir for lithium evaporation. A gas-carrier may be pumped through this tank. It can be an inert gas such as argon, helium, etc. The tank (4) preferably contains a door (6) which can have a metal seal for high temperature protection. A lithium cassette (7) may be installed inside the tank (4). A heater (8) is installed outside of the tank (4). The tank also has a nozzle (9) (inlet) for the gas-carrier connection. The tank is filled with lithium (e.g., in the form of pellets) in an inert atmosphere. The vol-ume of lithium is calculated based on required period of device working. The time period is determined by the inter-service or process maintenance interval of the equipment. For mass production, the interval is from 7 days and longer. The tank is equipped with a system of high temperature valves. These valves isolate the tank from the outside atmosphere during maintenance and repair operations. A spectrometer (5) for spectral control of lithium and cobalt can be installed at the end of the magnetron.

The method of LiCoO2 thin film formation (deposition) includes the deposition of LiCoO2 film on a substrate from metal cobalt (Co) target in lithium (Li) vapor by using of reactive magnetron sputtering in vacuum chamber. Deposition by reactive magnetron sputtering in a vacuum chamber. Control of lithium vapor flow is realized through the gas distributor (into the magnetron). The gas distributor is connected to the input of working gas and to the input of lithium vapor. The lithium vapor is preferably deliv-ered into the vacuum chamber by means of a gas-carrier flow e.g. through a heated tank with lithium. The tank with lithium is heated to a lithium melting point and preferably beyond for evaporation. The lithium vapor supply is controlled by changing the gas-carrier flow through the heated tank.

The invention is carried out as follows according to an embodiment of the invention. Preferably the lithium cassette is loaded into the tank. A e.g. cobalt target is placed in the magnetron system. The installation is pumped to high vacuum. Checking and degassing the targets and/or the lithium reservoir/tank are carried out. The lithium tank is then heated to lithium melting point (liquid state). The heating may be followed by fixing and maintaining this temperature for the duration of the operation. The valve in the gas distribution system for lithium vapor feeding and can remain closed. The entire gas distribution system may also be heated to the required temperatures.

Once the evaporation system and lithium vapor supply have reached the specified temperature, the working gas may be fed to the magnetron system. This is preferably an inert gas such as argon, helium, etc. The working gas flow then be switched on and can be brought up to set power parameters. Preferably after this, the lithium vapor valve (tap) may be opened to the magnetron. The opening can take place e.g. by means of the gas-carrier. By varying the gas-carrier flow through the lithium tank, the amount of lithium vapor to the magnetron system can be controlled. This will change the parameters of the discharge and the LiCoO2 film to be deposited. Deposition of the LiCoO2 film takes preferably place in the environment of Li+Ar+Ox+additional inert gas (optional). By changing the ratio of the working gases and lithium vapor, the stoichiometry of the LiCoO2 film can be changed within a very wide range.

The film deposition rate can also be varied. A spectrometer (5) can be used to control the deposition speed and stoichiometry of the LiCoO2 film. This spectrometer may be used for spectral control of the lithium and cobalt. This spectrometer can be mounted at the magnetron system end. Maintaining the Li/Co (Co/Li) ratio by magnetron discharge parameters (discharge voltage) and by the amount of lithium vapor, the required parameters of the deposited film and deposition rate are ensured. This enables a radical reduction in the cost of mass production of thin-film solid-state batteries (batteries) compared to the current magnetron technology.

The claimed method of LiCoO2 formation allows:
1. Increase the capacity of deposited material in comparison with composite LiCoO2 (LCO) target.
2. Increase the deposition rate by using a metal target. Metal target allows to use higher power densities. Increase the deposition rate by a greater variability in the using of the working gases.
3. It is simple and reproducible enough to create material concentration gradients in the same process over the layer thickness.
4. Decrease the production cost of a thin-film battery (cell) structure. Decrease the production cost by using simple deposition materials.

The production cost of mass-produced thin-film solid-state batteries (accumulators) is reduced by two factors:
1) Increased LiCoO2 film deposition rate (LCO) and hence an increased equipment productivity;
2) Using of more simple and cheap materials (metal cobalt targets and metal lithium pellets) instead of complex composite LiCoO2 targets. Increased deposition rate is possible because of using reactive magnetron sputtering of metal cobalt (metal cobalt target is more cheaper, than the composite LiCoO2 target, and cobalt deposition rate is 2.7 time higher, that LiCoO2 deposition rate, as metal cobalt target allows more power supply in comparison with LiCoO2 target) and delivering lithium vapor into area of cobalt magnetron sputtering (vacuum chamber) from the heated tank through gas distributor by using pumped gas-carrier (argon, helium, other).

1. Method of LiCoO2 film formation involving the deposition of a LiCoO2 layer on a substrate, the deposition is conducted by reactive magnetron sputtering of a metal cobalt (Co) target in lithium (Li) vapor onto a substrate in a vacuum chamber, the lithium tank is heated to lithium melting point, a gas-carrier flow is fed through the heated lithium reservoir which results in the controlled feeding of lithium vapor to a magnetron system via a gas distributor, wherein the gas distributor is connected to a working gas input and a lithium tank input, wherein the regulated supply of lithium vapor is carried out by changing the gas-carrier flow and the lithium vapor is supplied from a heated tank.

2. A technological LiCoO2 film forming device comprising a vacuum chamber with a magnetron system with a cobalt metal target, wherein the device also contains a gas distributor, which is located on one side of the magnetron system or around its perimeter, and a heated lithium tank, wherein the gas distributor is connected to an input of working gas, which is connected to the heated lithium tank via a tap and/or valve, wherein the tank is connected to a gas-carrier input.

3. The device according to claim 2 characterized by having a heated lithium tank either inside or outside the vacuum chamber.
